(19) United States
(12) Patent Application Publication
(10) Pub. No.: US 2011/0176346 A1
(43) Pub. Date: Jul. 21, 2011

(54) SEMICONDUCTOR MEMORY DEVICE

(75) Inventor: Yukio KATAMURA, Mie (JP)

(73) Assignee: KABUSHIKI KAISHA TOSHIBA, Tokyo (JP)

(21) Appl. No.: 13/007,086

(22) Filed: Jan. 14, 2011

(30) Foreign Application Priority Data
Jan. 19, 2010 (JP) 2010-009192

(51) Int. Cl. G11C 5/02

(52) U.S. Cl. 365/51

(57) ABSTRACT

According to one embodiment, semiconductor memory device including: a circuit substrate in which a circuit pattern is formed; a plurality of semiconductor memories mounted via a solder on both surfaces of the circuit substrate; a connector disposed at one end part of the circuit substrate for connection with a host device; and a resin mold part that seals the both surfaces of the circuit substrate. The resin mold part does not seal a region in which the connector is disposed and collectively seals regions in which the plurality of semiconductor memories are disposed.

### CROSS-REFERENCE TO RELATED APPLICATIONS

This application is based upon and claims the benefit of priority from the prior Japanese Patent Application No. 2010-9192, filed on Jan. 19, 2010; the entire contents of which are incorporated herein by reference.

### FIELD

Embodiments described herein relate generally to a semiconductor memory device.

### BACKGROUND

A semiconductor memory device provided with semiconductor memories such as a NAND flash memory has a configuration that the semiconductor memories are mounted via a solder on a circuit substrate on which a circuit pattern is formed. In the semiconductor memory device, the semiconductor memories and other surface-mount components are mounted on both surfaces of the circuit substrate due to a requirement of high-density mounting.

In the case where the semiconductor memories are mounted on the both surfaces of the circuit substrate, there is tendency that reliability of the semiconductor memory device is lowered because of lowering of reliability in a Thermal Cycling Test (TCT) caused by warping and deformation of the substrate. It is a general knowledge that the lowering of reliability in TCT tends to occur particularly when the semiconductor memories and other surface-mount components are symmetrically disposed on the surfaces of the circuit substrate. Suppression of the lowering of reliability in TCT has conventionally been performed by inserting an underfill resin material into a gap between the semiconductor memories and other surface-mount components and the circuit substrate. However, when an interval between the semiconductor memories or other surface-mount components is narrowed due to the requirement of high-density mounting, the underfill resin material is not orderly inserted into the gap to sometimes make it impossible to suppress the lowering of reliability in TCT. Accordingly, a technology of suppressing the lowering of reliability in TCT by displacing the surface-mount components such as semiconductor packages on both surfaces of the circuit substrate has been disclosed.

However, since the surface-mount components are displaced in the conventional technology, positioning of the surface-mount components is limited to reduce designing flexibility. Also, the limitation on positioning of surface-mount components can sometimes be an obstacle to realization of higher density mounting of the semiconductor memory device.

### BRIEF DESCRIPTION OF THE DRAWINGS

FIG. 1 is a diagram showing a surface of a semiconductor memory device according to a first embodiment;

FIG. 2 is a diagram showing a reverse surface of the semiconductor memory device shown in FIG. 1;

FIG. 3 is a sectional view taken along a line A-A of FIG. 1;

FIG. 4 is a partially enlarged sectional view showing gap portions between semiconductor memories and a circuit substrate;

FIG. 5 is a sectional view showing a semiconductor memory device according to Modification Example 1 of the first embodiment;

FIG. 6 is a sectional view showing a semiconductor memory device according to Modification Example 2 of the first embodiment;

FIG. 7 is a diagram showing a surface of a semiconductor memory device according to a second embodiment;

FIG. 8 is a diagram showing a reverse surface of the semiconductor memory device shown in FIG. 7;

FIG. 9 is a diagram showing a surface of a semiconductor memory device according to a third embodiment; and

FIG. 10 is a diagram showing a reverse surface of the semiconductor memory device shown in FIG. 9.

### DETAILED DESCRIPTION

In general, according to one embodiment, there is provided a semiconductor memory device that is provided with a circuit substrate in which a circuit pattern is formed, a plurality of semiconductor memories mounted on both surfaces of the circuit substrate, a connector disposed at one end part of the circuit substrate for connection to a host device, and a resin mold part that seals the both surfaces of the circuit substrate. The resin mold part does not seal a region in which the connector is disposed and collectively seals regions in which the plurality of semiconductor memories are disposed.

Exemplary embodiments of SEMICONDUCTOR MEMORY DEVICE will be explained below in detail with reference to the accompanying drawings. The present invention is not limited to the following embodiments.

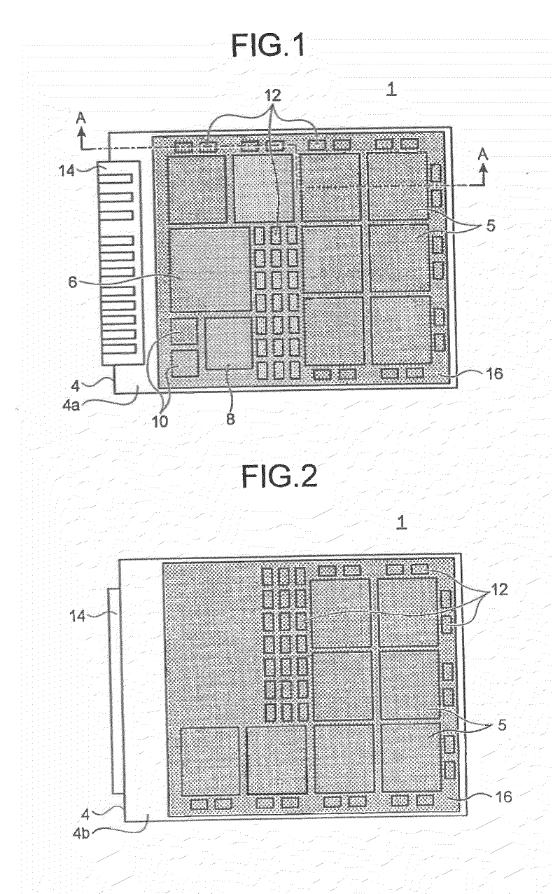

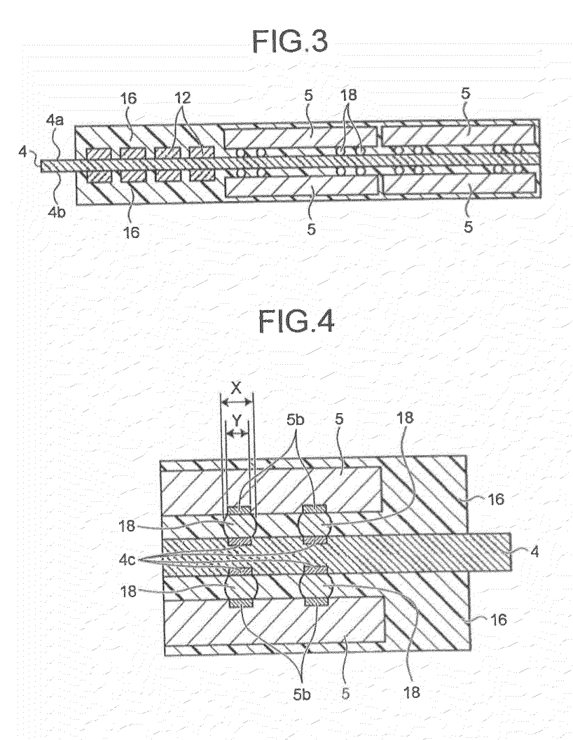

FIG. 1 is a diagram showing a surface of a semiconductor memory device according to a first embodiment. FIG. 2 is a diagram showing a reverse surface of the semiconductor memory device shown in FIG. 1. FIG. 3 is a sectional view taken along a line A-A of FIG. 1.

A semiconductor memory device 1 includes a circuit substrate 4, semiconductor memories 5, a controller 6, a Double-Data-Rate Synchronous Dynamic Random Access Memory (DDR SDRAM) 8, functional components 10, passive components 12, a connector 14, and a resin mold part 16.

The circuit substrate 4 has a multilayer structure in which synthetic resins are layered. Circuit patterns in various forms are formed on surfaces or insides of the layers formed of the synthetic resins. Surface-mount components such as the semiconductor memories 5 to be mounted on the circuit substrate 4 are electrically connected via the circuit patterns formed in the circuit substrate 4.

The semiconductor memories 5 are mounted on both surfaces of the circuit substrate 4 via a solder 18. The semiconductor memories 5 are BGA, LGA, TSOP, and QFP, for example. The semiconductor memory device 1 is formed by using the semiconductor memories 5 such as BGA. Thus, it is possible to attain improvement in data read performance, improvement in impact resistance, and suppression of power consumption. The semiconductor memories 5 are formed by stacking 8 stages of NAND flash memory chips having a rectangular shape of about 10 mm×13 mm and a thickness of about 80 μm, for example, in a plan view. Thus, the semiconductor memories 5 as a whole has a rectangular shape having the size of about 14 mm×18 mm and a thickness of about 1.46 mm, for example, in a plan view.

The controller 6 is mounted via a solder (not shown) on a surface 4a of the circuit substrate 4. The controller 6 receives commands such as a write request and a read request from a host device (not shown). The controller 6 causes predetermined processings to be executed by the semiconductor memories 5 in response to the received requests. The controller 6 may be mounted on a reverse surface 4b of the circuit substrate 4 or may be mounted on the both surfaces.

The DDR SDRAM 8 is mounted on the surface 4a of the circuit substrate 4 via a solder (not shown). The DDR SDRAM 8 is a system memory and enables high speed data transfer. The DDR SDRAM 8 may be mounted on the reverse surface 4b of the circuit substrate 4 or may be mounted on the both surfaces. The functional components 10 are mounted on the surface 4a of the circuit substrate 4 via a solder (not shown). Examples of the functional components 10 include a driver IC, for example. The functional components 10 may be mounted on the reverse surface 4b of the circuit substrate 4 or may be mounted on the both surfaces. The passive components 12 are mounted on the both surfaces of the circuit substrate 4 via a solder (not shown). Examples of the passive components 12 include a condenser, a resistance, and an electronic component such as an inductor, for example. The passive components 12 may be mounted on only one surface of the circuit substrate 4. In the following description, the surface-mount components other than the semiconductor memories 5, i.e. the controller 6, DDR SDRAM 8, functional components 10, and passive components 12, to be mounted on the circuit substrate 4 will be collectively referred to as element parts in some cases.

The connector 14 is disposed at one end part of the surface 4a of the circuit substrate 4. The connector 14 is mounted on the surface 4a of the circuit substrate 4 via a solder (not shown). The connector 14 is an interface that connects the host device such as a computer, the semiconductor memories 5, and the element parts.

The resin mold part 16 is formed by sealing the both surfaces of the circuit substrate 4 by a resin material. In the first embodiment, a region on the both surfaces in which the connector 14 is disposed is not sealed by the resin mold part 16. In contrast, as shown in FIGS. 1 and 2, regions in which the semiconductor memories 5 and the element parts are disposed are collectively sealed by the resin mold part 16. As shown in FIG. 3, the resin mold part 16 has a height that perfectly covers the semiconductor memories 5 and the element parts. The resin mold part 16 is formed by covering the both surfaces of the circuit substrate 4 on which the surface-mount components are mounted with a die and injecting a softened resin material into the die, for example.

As described above, since the both surfaces of the circuit substrate 4 are sealed by the resin mold part 16, it is possible to insert the softened resin material into a gap between the circuit substrate 4 and the surface-mount components from the gap between the semiconductor memories and the end of the surface-mount components. Therefore, it is possible to reliably fix the surface-mount components to the circuit substrate 4, thereby suppressing lowering of reliability in TCT. In general, it is considered that it is difficult to insert an underfill resin into the gap between the circuit substrate 4 and the surface-mount components by using a nozzle when an interval between the surface-mount components is 1.5 mm or less.

In contrast, in the case of sealing by the resin mold part 16, it is possible to insert a resin material into the gap between the circuit substrate 4 and the surface-mount components irrespective of the interval between the surface-mount components. Also, as a method of inserting the underfill resin, a jet type method has been known, but it is considered that it is difficult to insert the underfill resin when the interval between the surface-mount components is 0.5 mm or less. Even in the above-described case, the sealing by the resin mold part 16 enables to reliably insert the resin material into the gap between the circuit substrate 4 and the surface-mount components.

In the case where one surface of the circuit substrate 4 is sealed, influences of expansion and shrinkage of the resin mold part 16 are exerted only on the surface on which the resin mold part 16 is provided. Therefore, warping and deformation of the circuit substrate 4 tend to occur to easily cause cracking of the solder. Therefore, when the sealing is provided only on one surface, the reliability in TCT is worsened in some cases. In contrast, the both surfaces of the circuit substrate 4 are sealed by the resin mold part 16 in the first embodiment. Since the influences of expansion and shrinkage of the resin mold part 16 are substantially uniformly exerted on the both surfaces of the circuit substrate 4, the warping and deformation of the circuit substrate 4 are suppressed, thereby making it easy to suppress the lowering of reliability in TCT.

In the first embodiment, the semiconductor memories 5 and the passive components 12 are symmetrically disposed on the both surfaces of the circuit substrate 4. In general, it is known that the reliability in TCT tends to be reduced when the surface-mount components are symmetrically disposed on the both surfaces of the circuit substrate 4. The both surfaces of the circuit substrate 4 are sealed by the resin mold part 16 in the first embodiment. Since the resin material is inserted into the gap between the circuit substrate 4 and the surface-mount components, it is possible to suppress the lowering of reliability in TCT of the symmetrically disposed surface-mount components. Thus it is possible to attain high density mounting by the both surface mounting in the semiconductor memory device 1 while suppressing the reduction of designing flexibility and the lowering of reliability. Also, since the region in which the connector 14 is disposed is not sealed by the resin mold part 16, the resin mold part 16 hardly or never hinders the connection of the connector 14 to the host device.

FIG. 4 is a partially enlarged sectional view showing gap portions between the semiconductor memories 5 and the circuit substrate 4. As shown in FIG. 4, the semiconductor memories 5 are mounted by connecting lands 4c formed on the circuit substrate 4 and lands 5b formed on the semiconductor memories 5 each via the solder 18.

In the solder 18, an exposed surface that does not contact the lands 4c and 5b has a substantially spherical shape. Here, a maximum outer diameter of the solder 18 assuming the substantially spherical shape is represented by X, and a maximum outer dimension of the land in a plane view is represented by Y. In the case where X-Y is 0.15 mm or more when the semiconductor memory 5 is mounted to the circuit substrate 4, the semiconductor memory 5 is sealed by the resin mold part 16. Thus, it is possible to assure the reliability while suppressing the lowering of reliability in TCT.

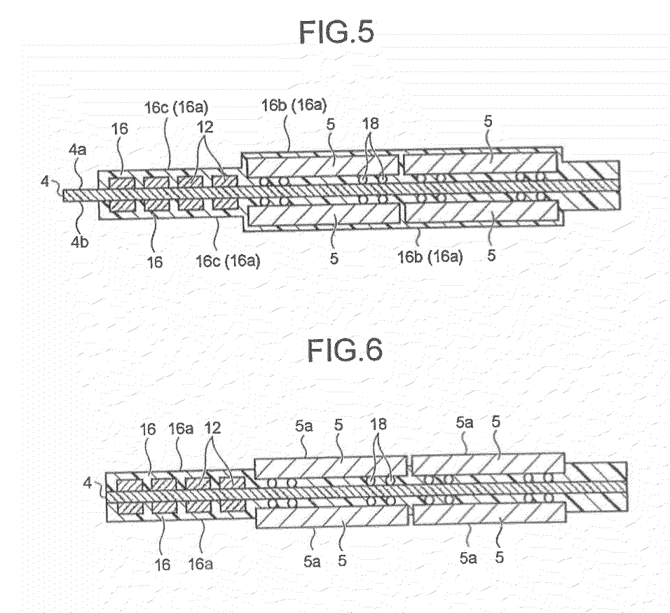

FIG. 5 is a sectional view showing a semiconductor memory device according to Modification Example 1 of the first embodiment. In Modification Example 1, as shown in FIG. 5, a step is formed on a top surface 16a of the resin mold part 16. More specifically, in the top surface 16a of the resin mold 16, a region 16c covering the element parts is lower than a region 16b covering the semiconductor memories 5. Thus, since the step is formed on the top surface 16a of the resin mold part 16, it is possible to reduce an amount of the resin material to be used for the resin mold part 16, thereby attaining a weight reduction and suppression of production cost of the semiconductor memory device 1. Also, the resin mold part 16 may be formed in such a manner that the top surface 16a of the region 16c of the resin mold part 16 is lower than a top surface of the element parts. With such resin mold part 16, it is possible to further suppress the use amount of the resin material.

FIG. 6 is a sectional view showing a semiconductor memory device according to Modification Example 2 of the first embodiment. In Modification Example 2, as shown in FIG. 6, the semiconductor memories 5 are not perfectly covered with the resin mold part 16, and the resin mold part 16 is formed in such a fashion that the top surface 16a is lower than top surfaces 5a of the semiconductor memories 5. It is possible to suppress a thickness of the semiconductor memory device 1 by lowering the top surface 16a of the resin mold part 16 to be lower than the top surfaces 5a of the semiconductor memories 5. In the case of using the semiconductor memory device 1 in a state where the semiconductor memory device 1 is housed in a housing, the thickness of the semiconductor memory device 1 is sometimes limited, but it is easier to deal with the limitation when the top surface 16a of the resin mold part 16 is lowered. Also, the resin mold part 16 may be so formed that the top surface 16a of the resin mold part 16 is lower than a top surface of the element parts. With such resin mold part 16, it is possible to further suppress the use amount of the resin material.

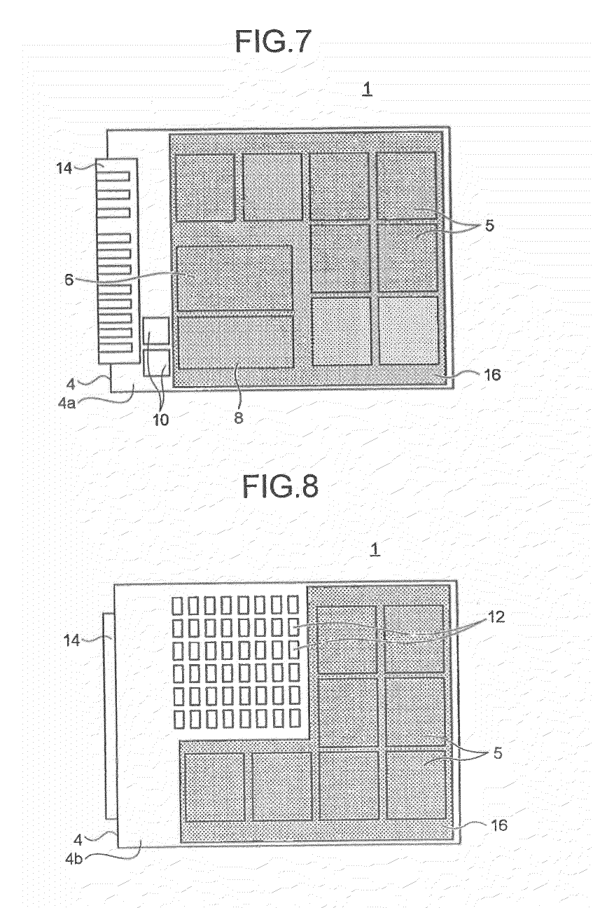

FIG. 7 is a diagram showing a surface of a semiconductor memory device according to a second embodiment. FIG. 8 is a diagram showing a reverse surface of the semiconductor memory device shown in FIG. 7. The component that is the same as that of the foregoing embodiment is denoted by the same reference numeral, and detailed description thereof is not repeated. In the second embodiment, the functional components 10 and the passive components 12 are disposed at positions that are separated from the resin mold part 16. In other words, the resin mold part 16 is formed so as not to cover the functional components 10 and the passive components 12.

Degree of influences to be exerted by the warping and deformation of the circuit substrate 4 on the surface-mount components, for example, a degree of being subject to cracking of the solder, is varied depending on the sizes of the surface-mount components. In general, when a planar size of the surface-mount component is small, the surface-mount component is less subject to the influences caused by warping and deformation of the circuit substrate 4, and the reliability in TCT is hardly lowered. Therefore, in the second embodiment, the resin mold part 16 is formed in such a fashion that the resin mold part 16 does not cover the functional components 10 and the passive components 12 having small planar sizes. More specifically, the functional components 10 and the passive components 12 that are surface-mount components each having the size of 4 mm□ or less in a planar size are not covered with the resin mold part 16.

Thus, it is possible to reduce the size of the resin mold part 16 and to reduce the amount of the resin material required for forming the resin mold part 16. Therefore, it is possible to reduce the resin material to be used for the resin mold part 16 while suppressing the lowering of reliability in TCT of the surface-mount components such as the semiconductor memories 5 that are more subject to the influences of warping and deformation of the circuit substrate 4 by the resin mold part 16, thereby attaining the weight reduction and the suppression of production cost of the semiconductor memory device 1.

In the second embodiment, all of the mounted functional components 10 and the mounted passive components 12 are not covered with the resin mold part 16, but the embodiment is not limitative. Even in the case of forming the resin mold part 16 in such a manner as not to cover a part of the mounted functional components 10 and a part of the mounted passive components 12, it is possible to attain the weight reduction and the suppression of production cost of the semiconductor memory device 1 while reducing the resin material to be used for the resin mold part 16.

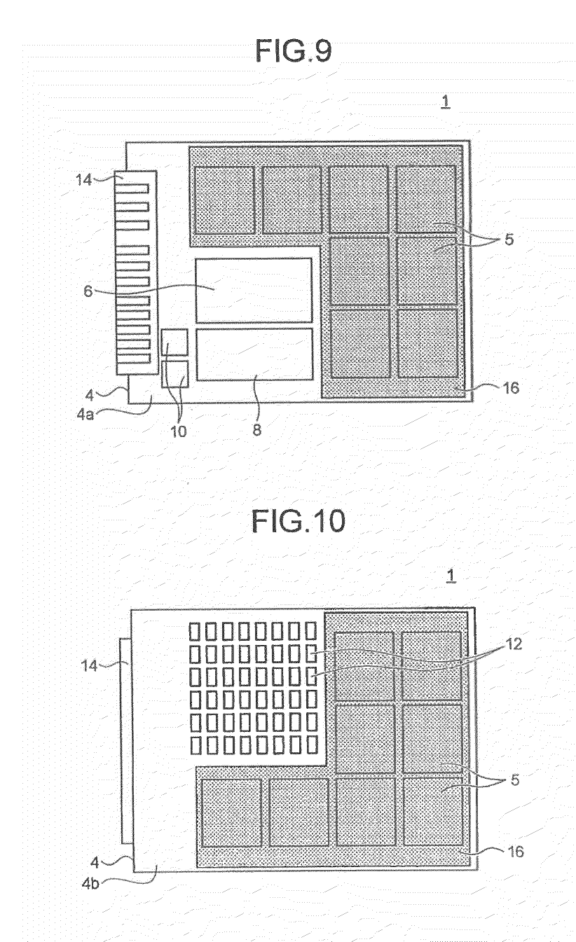

FIG. 9 is a diagram showing a surface of a semiconductor memory device according to a third embodiment. FIG. 10 is a diagram showing a reverse surface of the semiconductor memory device shown in FIG. 9. The component that is the same as that of the foregoing embodiment is denoted by the same reference numeral, and detailed description thereof is not repeated. In the third embodiment, only the semiconductor memories 5 that are symmetrically disposed on the both surfaces of the circuit substrate 4 are covered with the resin mold part 16. Thus, it is possible to reduce the size of the resin mold part 16 and to reduce the amount of the resin material required for forming the resin mold part 16.

As described above, it has been known that the reliability of the surface-mount components that are symmetrically disposed on the both surfaces of the circuit substrate 4 tends to be lowered in TCT. However, by covering only the semiconductor memories 5 that are symmetrically disposed on the both surfaces of the circuit substrate 4 and subject to the lowering of reliability in TCT with the resin mold part 16 as in the third embodiment, it is possible to reduce the resin material to be used for the resin mold part 16 while suppressing the lowering of reliability in TCT of the semiconductor memory device 1, thereby attaining the weight reduction and the suppression of production cost of the semiconductor memory device 1.

Though only the semiconductor memories 5 are symmetrically disposed in the third embodiment, the components other than the semiconductor memories 5 may be symmetrically disposed and may be covered with the resin mold part 16.

It may be possible for those skilled in the art to easily derive other effects and modification examples. Accordingly, a broader scope of the present aspect is not limited to the specific details and representative embodiments illustrated in the foregoing for explanatory purposes. Therefore, various alterations of the present invention are possible without departing from the scope and spirit of the entire concept of the invention that is defined by the accompanying claims and equivalents thereof.

While certain embodiments have been described, these embodiments have been presented by way of example only, and are not intended to limit the scope of the inventions. Indeed, the novel devices described herein may be embodied in a variety of other forms; furthermore, various omissions, substitutions and changes in the form of the devices described herein may be made without departing from the sprit of the inventions. The accompanying claims and their equivalents are intended to cover such forms or modifications as would fall within the scope and spirit of the inventions.

What is claimed is:

1. A semiconductor memory device comprising:
a circuit substrate in which a circuit pattern is formed;
a plurality of semiconductor memories mounted on both surfaces of the circuit substrate;
a connector disposed at one end part of the circuit substrate for connection with a host device; and
a resin mold part that seals the both surfaces of the circuit substrate, wherein
the resin mold part does not seal a region in which the connector is disposed and collectively seals regions in which the plurality of semiconductor memories are disposed.

2. The semiconductor memory device according to claim 1, further comprising a plurality of element parts mounted on at least one of the surfaces of the circuit substrate.

3. The semiconductor memory device according to claim 2, wherein the element parts are SDRAMs.

4. The semiconductor memory device according to claim 2, wherein the element parts are functional components.

5. The semiconductor memory device according to claim 2, wherein the element parts are passive components.

6. The semiconductor memory device according to claim 2, wherein the element parts are controllers.

7. The semiconductor memory device according to claim 1, wherein the semiconductor memories are symmetrically disposed on the both surfaces of the circuit substrate.

8. The semiconductor memory device according to claim 2, wherein at least a part of the element parts having a planer size of 4 mm□ or less is disposed at a position outside the resin mold part.

9. The semiconductor memory device according to claim 2, wherein the element parts are sealed by the resin mold part.

10. The semiconductor memory device according to claim 9, wherein the element parts are symmetrically disposed on the both surfaces of the circuit substrate.

11. The semiconductor memory device according to claim 1, wherein
the resin mold part is provided so as to cover the semiconductor memories; and
a top surface part of the resin mold part is formed in such a fashion that a region other than the regions covering the semiconductor memories is lower than the regions covering the semiconductor memories.

12. The semiconductor memory device according to claim 11, further comprising a plurality of element parts mounted on at least one of the surfaces of the circuit substrate, wherein
the element parts are sealed by another region of the resin mold part.

13. The semiconductor memory device according to claim 12, wherein the element parts are symmetrically disposed on the both surfaces of the circuit substrate.

14. The semiconductor memory device according to claim 11, wherein a top surface of the another region of the resin mold part is higher than a top surface of the element parts.

15. The semiconductor memory device according to claim 11, wherein a top surface of the another region of the resin mold part is lower than a top surface of the element parts.

16. The semiconductor memory device according to claim 1, wherein the top surface of the resin mold part is lower than top surfaces of the semiconductor memories.

17. The semiconductor memory device according to claim 16, further comprising a plurality of element parts mounted on at least one of the surfaces of the circuit substrate, wherein
the element parts are sealed by the resin mold part; and
a top surface of the resin mold part is higher than top surfaces of the element parts.

18. The semiconductor memory device according to claim 16, further comprising a plurality of element parts mounted on at least one of the surfaces of the circuit substrate, wherein
the element parts are sealed by a the resin mold part; and
a top surface of the resin mold part is lower than top surfaces of the element parts.

19. The semiconductor memory device according to claim 1, wherein
a land to be electrically connected to the semiconductor memories are formed on the circuit substrate;
the semiconductor memories are mounted on the circuit substrate via a solder positioned above the land; and
a maximum outside dimension of the land in a plan view is smaller than a maximum outside dimension of the solder.
